(19) United States
(12) Patent Application Publication
(10) Pub. No.: US 2014/0097491 A1
(43) Pub. Date: Apr. 10, 2014

(54) Dielectrically Terminated Superjunction FET

(71) Applicant: TEXAS INSTRUMENTS INCORPORATED, Dallas, TX (US)

(72) Inventor: Constantin Bulucea, Sunnyvale, CA (US)

(73) Assignee: TEXAS INSTRUMENTS INCORPORATED, Dallas, TX (US)

(21) Appl. No.: 13/645,934

(22) Filed: Oct. 5, 2012

(51) Int. Cl. H01L 29/78

(52) U.S. Cl. 257/341; 257/E29.262

(57) ABSTRACT

A dielectrically-terminated superjunction field-effect transistor (FET) architecture for use in high voltage applications. The architecture adds a dielectric termination to general features of a high voltage superjunction process. The dielectrically-terminated FET (DFET) is more compact and more manufacturable than a conventional, semiconductor-terminated superjunction FET.

### BACKGROUND

1. Technical Field

The patent relates to Power MOS Field Effect Transistors (FETs) and, more particularly, to a Superjunction FET.

2. Background Art

Superjunction FETs can be fabricated with alternating pillars of p-type and n-type conductivity type material in the active region and a dielectric pillar in the termination region.

Typically, in vertically conducting FETs the electrodes are disposed on two opposing planes. When the vertical FET is turned on, electric current flows along the along the channel, and then the thickness (i.e. vertical direction) of the semiconductor device in a so-called drift region. When the device is turned off, depletion regions extend vertically. To realize high breakdown voltage for a vertical semiconductor device, the drift region between the channel and drain electrode can be made from a high resistivity material and have a relatively large thickness. However, the high resistivity and the relatively large thickness of the drift layer increases the on-resistance of the device. A higher on-resistance adversely affects the performance of the device by increasing the conduction loss and lowering the switching speed. It is well known that on-resistance of a device rapidly increases in proportion to the 2.5^{th} power of a breakdown voltage.

One technique to overcome this problem has been to use a semiconductor device with a particular structure of the drift region. Such semiconductor device includes alternating pillars of opposite conductivity type material formed in a drift layer in the active region of the device. The alternating pillars of the opposite conductivity type material still provides a current path when the device is turned on while depleting the drift region horizontally to withstand the reverse voltage when the device is turned off.

In a superjunction FET, the reverse-bias electric field is essentially constant in the vertical direction, hence the breakdown voltage of the device can be approximated by the product of the thickness of the drift layer and the critical, or breakdown electric field in silicon. In particular, if the charge quantities in the alternately arranged pillar of high concentration n-type and p-type material are in equilibrium with each other, the breakdown voltage becomes less independent of the resistivity of the drift layer. For this reason reducing the resistivity of the drift layer leads to a smaller drop in breakdown voltage, thus realizing high breakdown voltage and low on-resistance at the same time.

Despite the above advantages, the superjunction FET has a drawback in that it is difficult to stably implement a termination region surrounding the active region. This is because the low resistivity of the drift layer (possible due to super junction design) causes the lateral electric field distribution in the transition region from the active region to the termination region to be non-uniform, thus reducing the overall breakdown voltage of the device. As a result, the breakdown voltage in the termination region may be undesirably lower than in the active region.

One approach achieving high breakdown voltage in the termination region is to provide termination pillars to spread the depletion regions outside the active region, by extending the superjunction infrastructure into the termination region, the benefits of the lateral charge balancing is also extended into that region. That is, a 10 times more heavily doped material than normally required to withstand a given reverse voltage will also withstand that voltage.

At a closer analysis one can easily observe that the superjunction effect is obtained, at its full extent, only in the FET array region as shown in FIG. 1, where the superjunction pillars are biased at the source potential and so deplete towards the ideal superjunction condition of full lateral depletion when the high voltage is applied to the drain. Beyond the transition pillars, into the termination region, the pillars are not connected and so remain floating to pick up whatever potential their location takes from the field created by the biased electrodes and pillars.

This type of termination is inefficient in terms of silicon area it takes.

Because of the above limitations there is a need to provide a more compact and more manufacturable superjunction FET than the current conventionally designed, semiconductor-terminated superjunction FETs.

What is the needed is a cost-effective high-voltage FET that capitalizes better on the advantages of the superjunction device architecture. The cost-effective language refers to the minimization of the total area occupied by the transistor die at pre-imposed breakdown voltage and ON resistance, where the total area includes the active area occupied by the transistor array and the termination area around it.

### SUMMARY

In accordance with an embodiment of the present invention, an apparatus is provided. The apparatus comprises a substrate having a first region of a first conduction type; a plurality of array pillars of a second conduction type formed in a second region of the substrate and extending to a first depth, wherein the second region is located within the first region, and wherein the plurality of array pillars are substantially parallel to one another; a boundary pillar of the second conduction type formed along the periphery of the second region and extending to the first depth; a plurality of array wells formed in the second region of the substrate and extending to a second depth, wherein each array well is at least partially coextensive with at least one of the array pillars, and wherein the first depth is greater than the second depth; a biasing well formed in the second region of the substrate and extending to the second depth, wherein the biasing well is at least partially coextensive with at least one of the array pillars and the boundary pillar; a termination pillar formed in the first region of substrate along the periphery of the of the second region and extending to a third depth, wherein the termination pillar abuts the boundary pillar, and wherein the third depth is greater than the first depth; a boundary gate dielectric strip formed over at least a portion of the biasing well; a plurality of array gate dielectric strips, wherein each array gate dielectric strip is located between at least two of array pillars, and wherein each array gate dielectric is formed over at least a portion of two array wells; a boundary gate conductor that is formed over at least a portion of the termination pillar and over at least a portion of the boundary gate dielectric strip; a plurality of array gate conductors, wherein each array gate conductor is formed over at least a portion of at least one of the array gate dielectric strips; a first electrode that is formed over at least a portion of the second region of the substrate so as to couple the plurality of array wells and the boundary well together; a second electrode formed over at least a portion of the termination pillar so as to couple the plurality of array gate conductors and the boundary gate conductor together; and a third conductor formed over the substrate along the periphery of the first region.

In accordance with an embodiment of the present invention, the termination pillar further comprises a termination pillar trench; a vacuum-filled region formed within the termination pillar trench; and a termination pillar dielectric layer formed within the termination pillar trench and substantially surrounding the vacuum-filled region.

In accordance with an embodiment of the present invention, the first electrode is formed over the plurality of array gate conductors, and wherein an isolation dielectric layer is located between each of the array gate conductors and the first electrode.

In accordance with an embodiment of the present invention, the substrate further comprises: a first substrate layer; a second substrate layer that underlies the first substrate layer.

In accordance with an embodiment of the present invention, the array wells are of the second conduction type.

In accordance with an embodiment of the present invention, the biasing well is of the second conduction type.

In accordance with an embodiment of the present invention, the first conduction type is N-type, and the second conduction type is P-type.

In accordance with an embodiment of the present invention, the plurality of array conductors and the boundary gate conductor are formed of polysilicon, and wherein the first, second, and third conductors are formed of aluminum, and wherein the first substrate layer is an epitaxial layer.

In accordance with an embodiment of the present invention, the termination pillar dielectric layer further comprise: a thermally grown silicon dioxide layer; and a deposited dielectric layer formed over the thermally grown silicon dioxide layer.

In accordance with an embodiment of the present invention, an apparatus is provided. The apparatus comprises a substrate having: a first layer of a first conduction type with a first doping concentration; and a second layer of the first conduction type with a second doping concentration that is formed over the first layer, wherein the first doping concentration is greater than the first doping concentration; a field effect transistor (FET) array having: a first set of pillars of a second conduction type formed in the second layer of the substrate, wherein the pillars from the first set of pillars are substantially parallel to one another, and wherein each pillar from the first set of pillars extends to a first depth; a first set of wells formed in the first layer, wherein each well from the first set of wells is at least partially coextensive with at least one of the pillars from the first set of pillars; a first set of gate dielectric strip formed over the second layer of the substrate, wherein each gate dielectric strip is located between at least two of the pillars from the first set of pillars; a first set of gate conductors, wherein each gate conductor from the first set of gate conductors is formed over at least a portion of at least one of the gate dielectric strips from the first set of gate dielectric strips; and a set of gate isolators, wherein each gate isolator is formed over at least a portion of at least one of the gate conductors from the first set of gate conductors; a terminator having: a second set of pillars of the second conduction type formed in the second layer of the substrate, wherein the second set of pillars substantially surround the first set of pillars; a dielectric pillar formed in the second layer of the substrate and abutting the second set of pillars, wherein the dielectric pillar extends to a second depth, and wherein the second depth is greater than the first depth; a second set of wells formed in the second layer of the substrate, wherein each well from the second set of wells is at least partially coextensive with at least one pillar from each of the first and second sets of pillars; a second set of gate dielectric strips, wherein each dielectric gate strip from the first set of gate dielectric strips is formed over at least a portion of at least one of wells from the second set of wells; a second set of gate conductor, wherein each gate conductor from the second set of gate conductors is formed over the at least a portion of the dielectric pillar and at least one of the gate dielectric strips from the first set of gate dielectric strips; a first electrode that is formed over the gate isolators and that couples the wells from the first and second sets of wells together; a second electrode formed over at least a portion of the dielectric pillar so as to coupled to the gate conductors from the first and second sets of gate conductors together; and a third conductor formed over the substrate and spaced apart from the second electrode.

In accordance with an embodiment of the present invention, the dielectric pillar further comprises: a trench; a vacuum-filled region formed within the trench; and a pillar dielectric layer formed within the trench and substantially surrounding the vacuum-filled region.

In accordance with an embodiment of the present invention, the first set of wells are of the second conduction type having a third doping concentrations, respectively, wherein the third doping concentration is greater than the second doping concentration.

In accordance with an embodiment of the present invention, wherein the first and second sets of pillars have a fourth doping concentration that is less than the third doping concentration.

In accordance with an embodiment of the present invention, the second set of pillars further comprise a boundary pillar, and wherein the second set of wells further comprises a biasing well is of the second conduction type.

In accordance with an embodiment of the present invention, the gate conductors are formed of polysilicon, and wherein the first, second, and third conductors are formed of aluminum, and wherein the first substrate layer is an epitaxial layer.

In accordance with an embodiment of the present invention, the termination pillar dielectric layer further comprise: a thermally grown silicon dioxide layer; and a deposited dielectric layer formed over the thermally grown silicon dioxide layer.

### BRIEF DESCRIPTION OF THE DRAWINGS

Example embodiments are described with reference to accompanying drawings wherein:

FIG. 1 shows a simplified example of a conventional superjunction FET with field-plated superjunction termination illustrating the electric field distribution in silicon when the device is biased at 500 V.

FIG. 2 is a comparative top view drawing of a conventional 600 volt FET on the lefts side and a conventional 900 volt FET on the right side using superjunction terminations with floating field plates.

FIGS. 3a-3c are perspective views of an example of the superjunction FET with dielectric termination.

FIG. 4 is a top view of a conventional superjunction FET with field-plated superjunction termination.

FIG. 5 is a top view of a dielectrically terminated superjunction FET of FIGS. 3a to 3c.

FIGS. 6 and 7 are example qualitative descriptions of the field structure in the superjunction FET of FIGS. 3a to 3c.

FIG. 8 is an example qualitative description of the equipotential lines in the superjunction FET of FIGS. 3a to 3c.

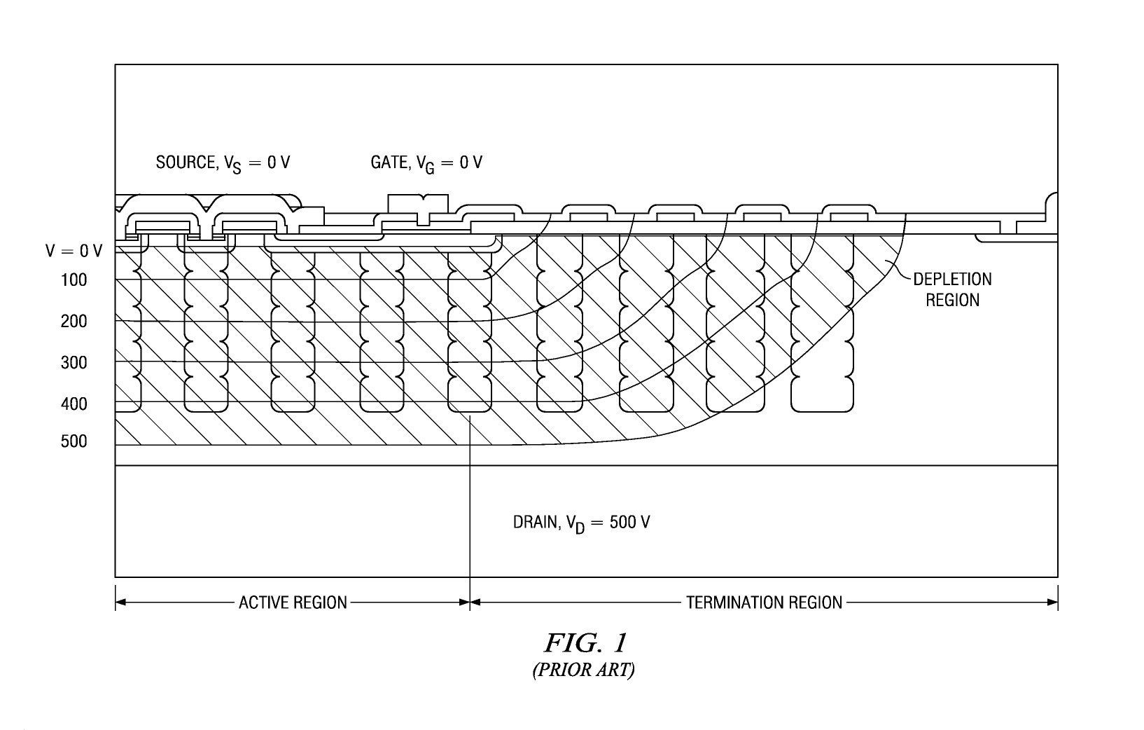

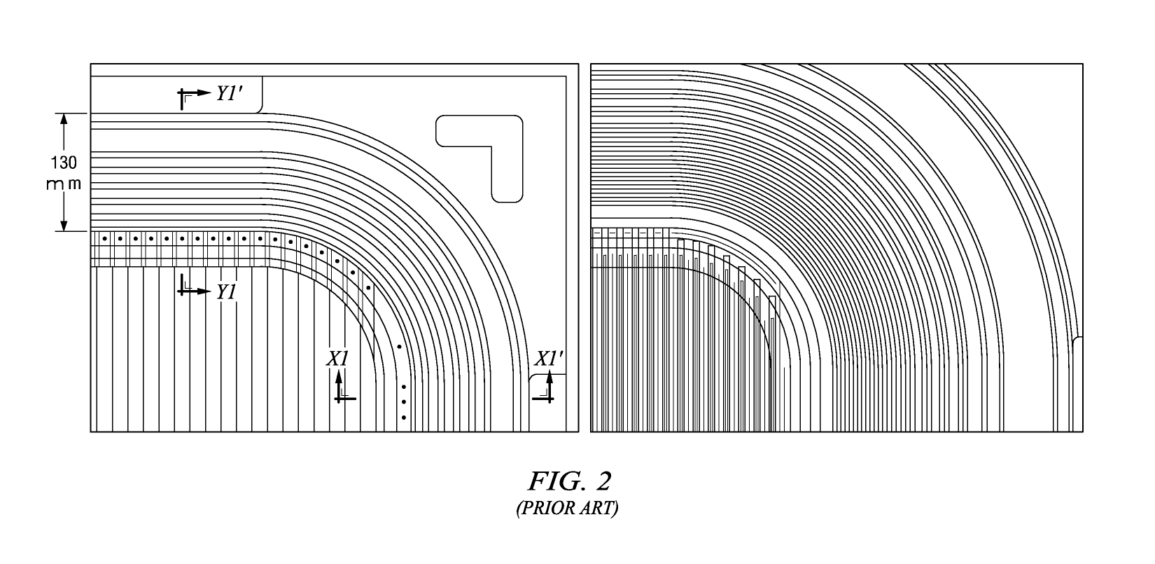

### DETAILED DESCRIPTION

Example embodiments are given of apparatus and methods for an improved superjunction FET in which the active area of a superjunction FET is laterally enclosed into an open-bottom dielectric tub. In one example embodiment, the dielectric separation (wall) is interposed between the superjunction array and the termination region thereby facilitating the lateral transition from the virtually intrinsic background material created by the superjunction effect to the plain epitaxial material available in the termination region. In this example embodiment, the voltage difference from the high potential of the drain to the reference potential of the source essentially drops on the dielectric wall, which has a much higher breakdown field than the semiconductor background material.

An advantage of this example embodiment is that the dielectrically terminated FET (DFET) is more compact than a conventional semiconductor-terminated superjunction FET and enables a more efficient use of breakdown voltage capability of an array of superjunction FETs. Specifically, the DFET includes a dielectric termination based on a trench that encloses the transistor array and is partly filled with a dielectric material.

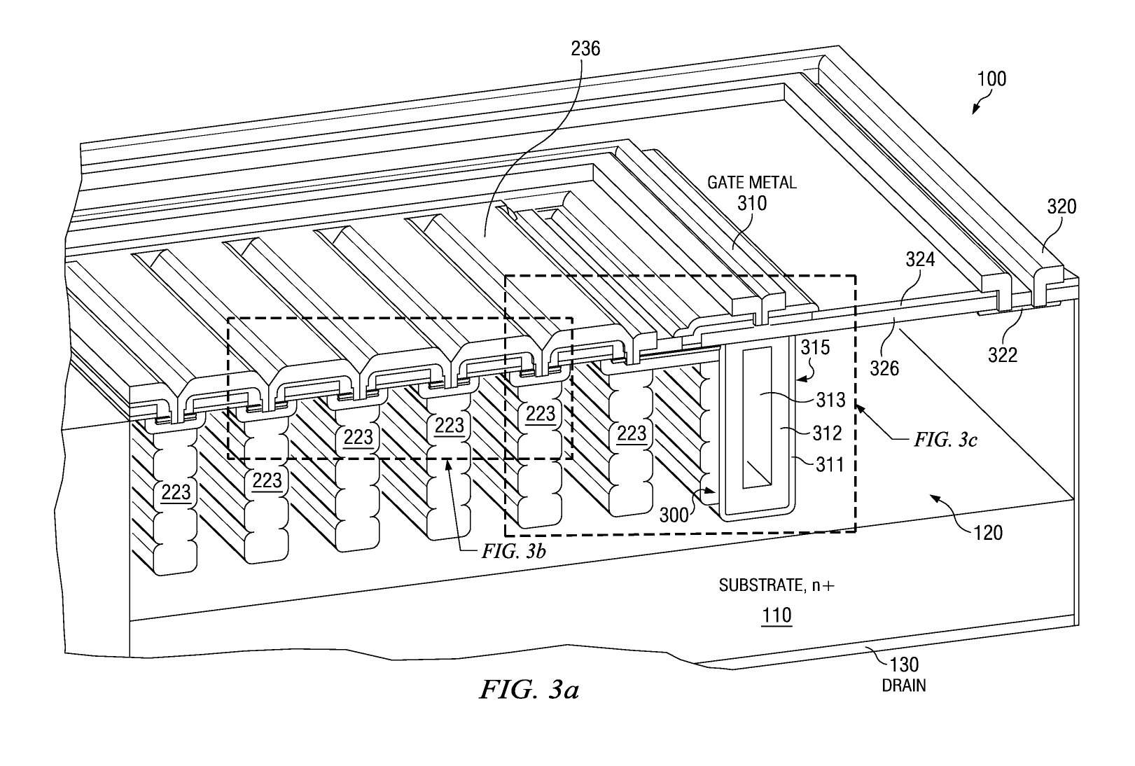

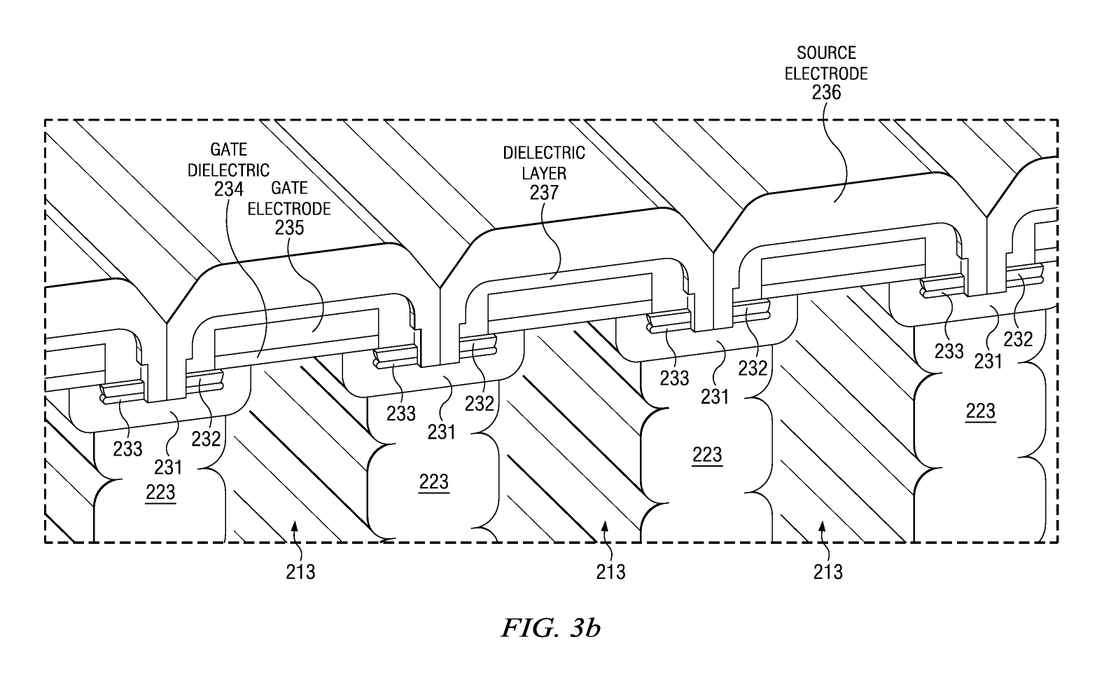

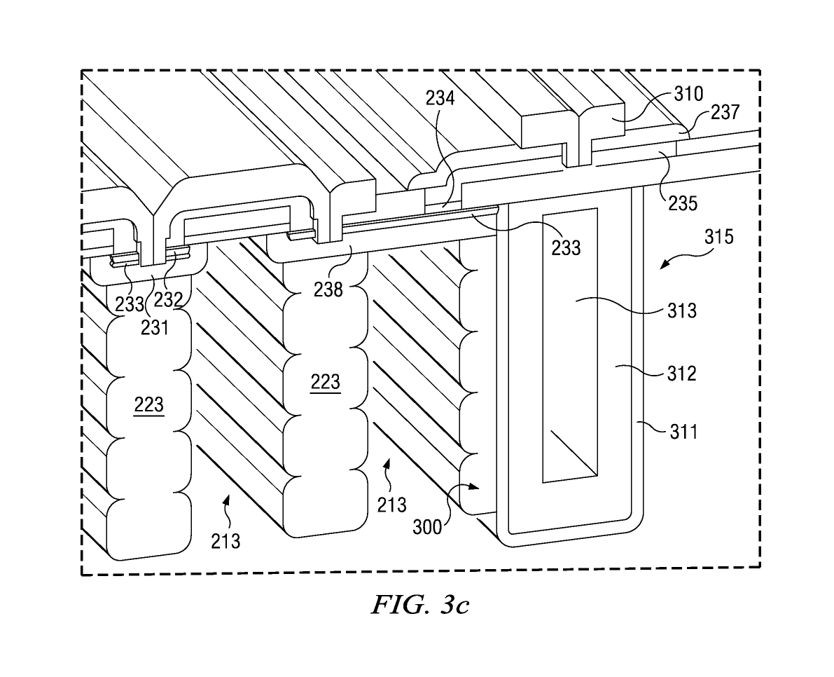

In FIG. 3a, an example superjunction FET 100 can be seen, which typically includes an active region and a termination region. Although it is not explicitly shown in FIG. 3a, the termination region can substantially surrounds the active region (which can include a FET array). As shown in this example, a drain electrode 130 can be formed on one side of the substrate 110 (which can, for example, be an n+ type material) and, for example, an epitaxial layer 120 (which can, for example, be formed of an n− material) can be formed on the other. Collectively, these layers can be referred to as a substrate. Within layer 120, pillars 213 and 223 can be formed in the active region. These pillars 213 and 223 can formed of alternating n-type and p-type materials and can be formed so as to be substantially parallel to one another. Collectively, the pillars 213 and 223 can form at least a portion of the FET array. Boundary or buffer pillar 300 (which can, for example be formed of p-type material) can be formed along the periphery of the active region so as to at least in part function as a transition between the active region and the termination region. As shown in this example, pillars 223 do not extend through the entire depth of layer 120, and, also as shown in this example, pillars 213 are formed of layer 120; the bottom of the FET array are separated from the substrate 110 by the intervening portion of layer 120. Alternatively, the bottom of the FET array can extend to and be in contact with substrate 110

A number of planar gates for the FET array are shown in the example of FIG. 3b. The planar gate structures include well regions 231, source regions 232, and contact regions 233, gate insulating layer or gate oxide layer 234, and gate electrodes (e.g., gate polysilicon layer 235). The well regions 231 (which can, for example, be formed of a lightly doped p-type or p− material) are typically located over and in contact with the top surfaces of pillars 223 so as to at least be partially coextensive with the pillars 223. As shown in this example, two source regions 232 (which can, for example, be highly doped n-type or n+ material) are formed in well region 231. A well contact region 233 (which can, for example, be formed of a highly dopes p-type or p+ material) is formed in well region 231 beneath two sources regions 232. Collectively, the well regions 231 and well contact regions 233 can form a transistor body. A gate insulating layer 234 (which can, for example, be formed of silicon dioxide) and an overlying gate electrode 235 (which can, for example, be formed of polysilicon) are formed over pillars 213 and well region 231 so as to extend between two adjacent source regions 232. These gate electrodes 235 are then, in this example, commonly coupled together with a gate metal layer 310 (which can, for example, be formed of aluminum). A source electrode 236 (which can, for example, be formed of aluminum) is formed over the gate electrodes 235 and is coupled to the source regions 232 and well contact regions 233 (indicating that the body and source are coupled together. Gate electrode 235 and source electrode 236 are also electrically insulated from each other by an insulating layer 237.

Along the periphery of the FET array, the planar gates (which can be seen in FIG. 3c) can have a slightly different configuration. As shown, there is a biasing or boundary well 238 extending between so as to be at least partially coextensive with boundary pillar 300 and at least one of the pillars 223. This biasing well 238 can be located along both ends of the FET array or along the periphery of the FET array. Formed in well 238 is a contact region 233 over which a gate dielectric layer 234 and gate electrode 235. An advantage for this configuration is that the gate electrode 235 (which extends over the well 238) can also extend over the termination pillar 315 so that that a gate ring (e.g., formed of layer 310) can be formed.

In operation, when the FET 100 is turned on by applying the proper biasing to the gate, drain, and source electrodes, an inversion layer is formed in the channel regions (i.e., within well regions 231). A current path from source regions 232 laterally through the channel region, and then vertically through pillars 213, layer 120, substrate 110, and drain electrode 130 is formed. Current flow between source electrode 236 and drain electrode 130 is thus established. When the FET 100 is turned off, no current flows between the source and drain terminals, and the diode formed by the drain and well regions (e.g., 110 and 231) is reverse biased. The reverse bias causes a depletion region to extend in both the pillars 223 and 213. The pillars 213 and 233 are depleted efficiently since the depletion region extends in both directions at substantially the same time. This makes it possible to reduce the on-resistance by increasing the doping concentration in pillars 213 without adversely impacting the breakdown characteristics.

Referring back to FIG. 3a, termination pillar 315 in FET 100, as shown in this example, laterally encloses the FET array in an open-bottom dielectric tub. Typically, a trench is formed in layer 120 (which can be referred to as a termination trench). The termination trench is usually deeper than the pillars 223 of the FET array and is usually lined with a thin layer of thermally grown silicon dioxide 311 to ensure a semiconductor-dielectric interface that is naturally clean of undesirable interface defects such as fixed and mobile charges, quantum surface states, or dislocations. A dielectric layer 312 can then be deposited inside the trench (e.g. over layer 311). A sealed-off empty or vacuum-filled region 313 can be formed within the termination pillar 315 for reducing the material stress associated with the thermal-expansion-related forces inside a trench completely filled by conventional sideway deposition. The presence of an empty region 313 inside the termination dielectric comes with the added “free” advantage of benefitting from the ideal dielectric constant of the vacuum. As shown, the termination trench is buffered inwardly by a pillar 300 of the same doping profile and vertical structure as the pillars 223. The buffer pillar 300 can be created at the same time with the array pillars. In the ideal case when no other charges than those resulting from semiconductor depletion are present, the buffer pillar 300 can be half of the width of the array pillars, for theoretically perfect charge balancing. Otherwise, its width may be varied to balance charges present in the oxide or at the silicon-oxide interfaces, as shown later in this section.

Also, as shown in FIG. 3a, a drain equipotential ring is shown. Typically, there is a deposited dielectric layers 324 and 326 that is formed over the pillar 315 and that extends to the drain equipotential ring. The drain equipotential ring generally comprises a drain well 322 that is formed in layer. This layer 322 can, for example, be an heavily doped n-type or n+ material, and a metal layer 320 (which can, for example, be formed of aluminum) is, in this example, formed over dielectric layer 324 to form a metal ring. This ring (i.e., metal layer 320) is in electrical contact with well 322.

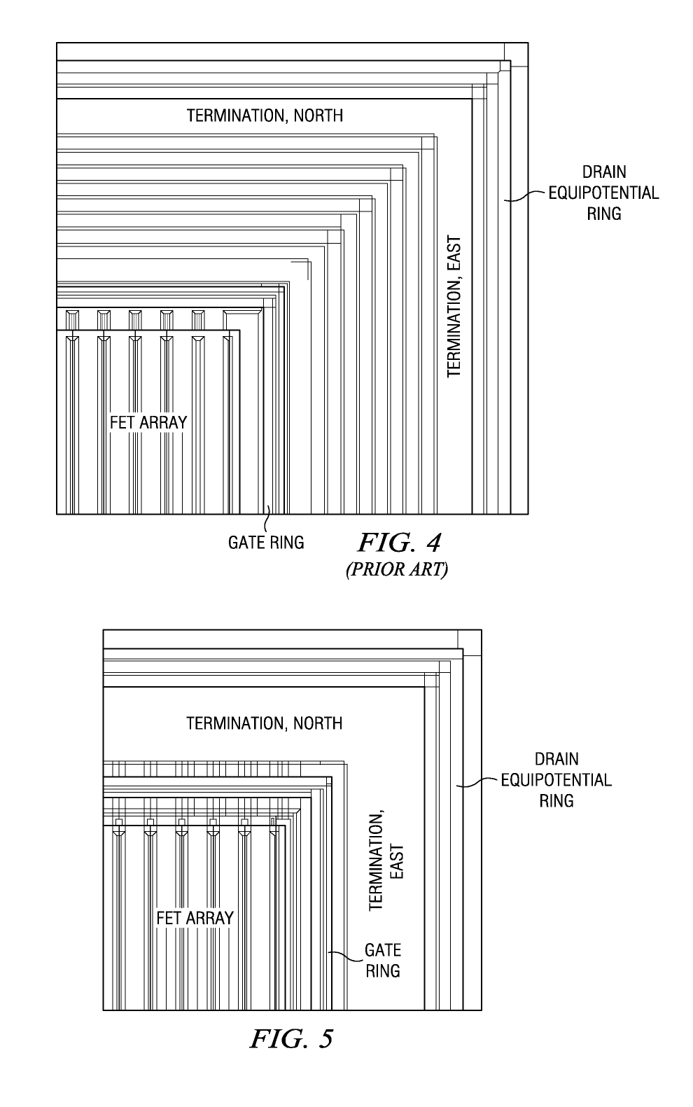

The DFET architecture is more compact than the one of a conventional superjunction FET, as can be seen by comparing the top view in FIG. 5 with its conventional counterpart in FIG. 4. In this comparison, one should know that the array portions of the FETs captured in these representations have been chosen to be equal to enable comparison of the areas occupied by the termination regions and that the two drawings are at the same magnification scale.

Depending on the voltage specification, the termination of a dielectrically termination superjunction FET can occupy less than half of the area of an alternate superjunction architecture using floating junctions and field plates in the termination region.

An independent advantage of the example embodiment of DFET architecture is the reduction in termination component of the gate-to-drain (feedback) capacitance by placing the gate ring on the top of the termination trench. This advantage is more important in devices designed for low-current applications and translates into improved switching speed of the transistor.

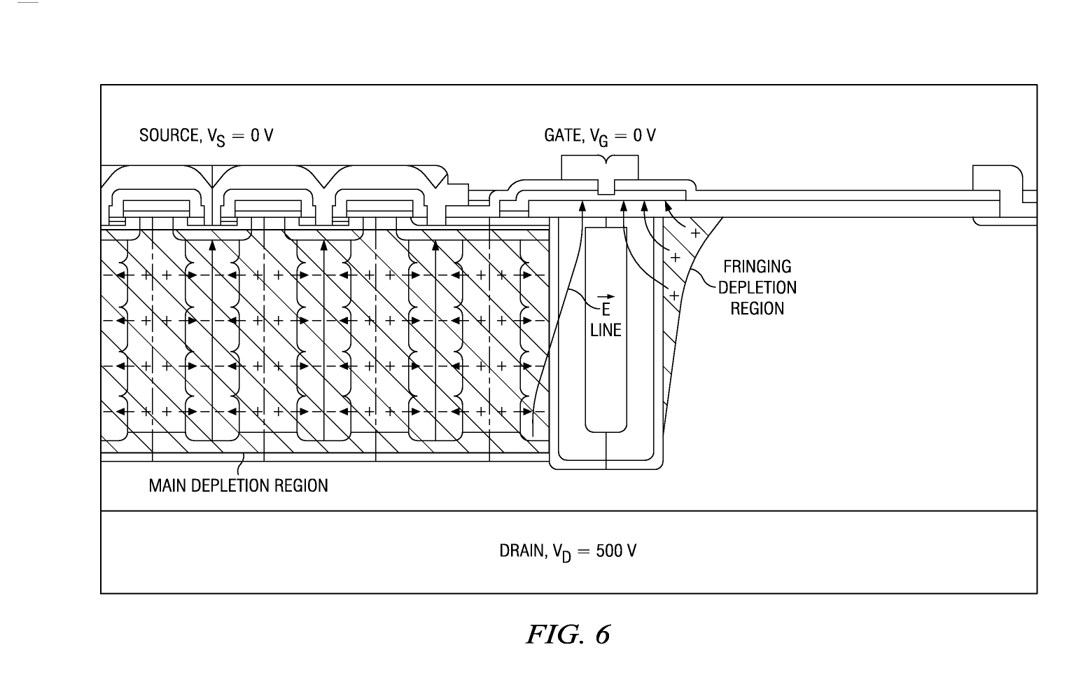

FIG. 6 illustrates the various features of the example embodiment of the DFET illustrated in FIG. 3 including the field structure in a dielectrically terminated superjunction FET. When the device is biased as shown, for the conventional BV_{DSS} (V_{G}=0) condition:
In the superjunction FET array region, orthogonal charge balancing takes place in the horizontal direction (the superjunction charge balancing) and in the vertical direction (the intrinsic diode charge balancing). The FET array region is fully depleted and is referred to as main depletion region.
Towards the periphery of the superjunction array, and continued inside the dielectric wall and slightly into the termination portion of the semiconductor background, the field departs from the orthogonal structure described before and has a true 2-dimensional structure. In this region, the negative charges induced by the field on the grounded polysilicon gate electrode, here treated as a metal, are balanced by the positive charge of the ionized donors in the depleted n-type drain region. The depletion region outside the termination wall is referred to as fringing depletion region. The arrow-terminated lines marked “\vec{E} Line” are field lines the tangent to which, in any point, provide the direction of the electric field in that point.

In judging the field structure of a dielectrically terminated superjunction FET in comparison to a conventional superjunction FET with floating junctions and field plates, one should consider the implications of the different dielectric constant of silicon and silicon dioxide or vacuum.

In the analysis to follow, we will simplify the problem to a silicon-dioxide filled trench, knowing that the relative dielectric constant of silicon dioxide (∈ᵣ=3.9) is 3 times smaller than that of silicon (∈ᵣ=11.7)⁶.

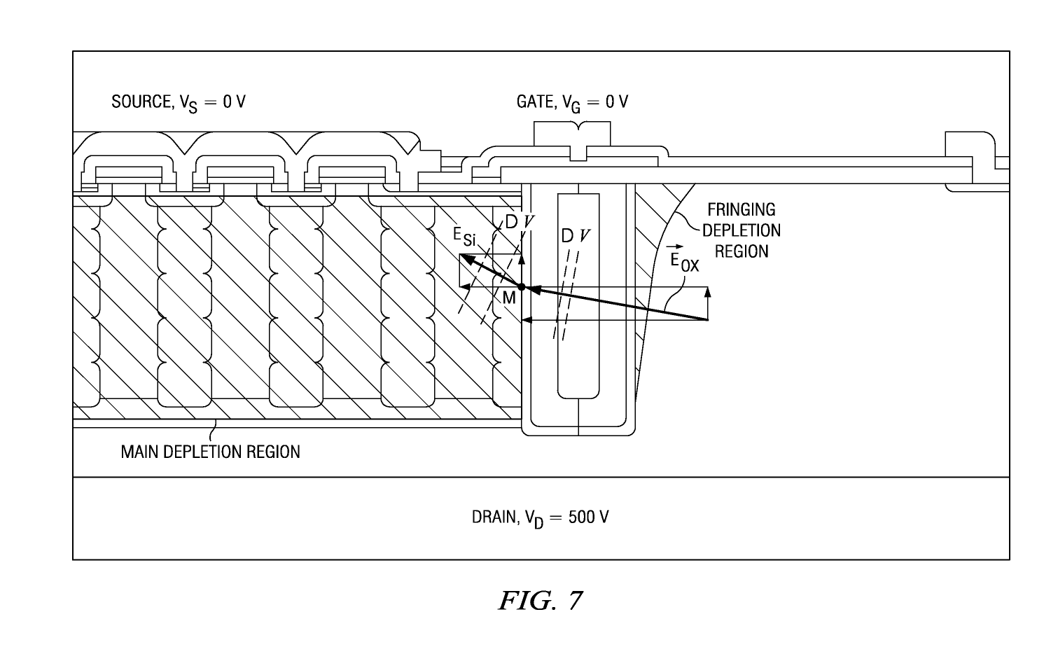

FIG. 7 is a graphical construction of the electric field vectors around a point M along the silicon/silicon-dioxide interface.

Assuming an ideal dielectric, with no interface or bulk charges, Gauss Law of the electric field theory requires the normal component of the electric induction vector to be continuous across such an interface, i.e., in customary notations,

∈₀∈_{r(Si)}E_{n(Si)}=∈₀∈_{r(Ox)}E_{n(Ox)}, (1)

hence

$${E}_{n ( ox )} = \frac{{ɛ}_{Si}}{{ɛ}_{Ox}} {E}_{n ( Si )} = 3 {E}_{n ( Si )} . \qquad ( 2 )$$

On the other hand, the Law of Electromagnetic Induction (Faraday's Law) requires that the tangential components of the electric field are conserved across the interface, i.e.,

E_{t(Si)}=E_{t(Ox)}. (3)

Equations (2) and (3) enable the graphical construction in FIG. 7, illustrating how the electric field vector refracts at the silicon/silicon-dioxide interface, with the following two advantages for the proposed architecture:

The electric field is substantially stronger in the oxide and applied high voltage can predominantly drop across it; this is advantageous, because the silicon dioxide can take about 20 times higher fields than silicon before breakdown.

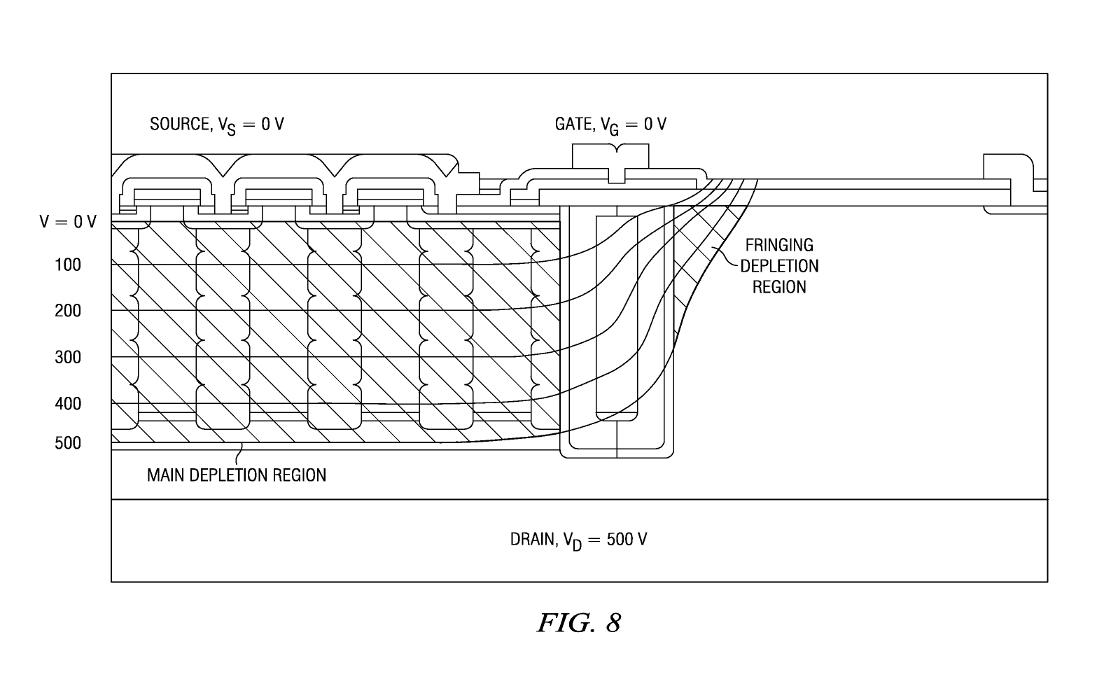

The equipotential lines change orientation towards a better lateral confining of the fringing-field region (fringing depletion region). A qualitative description of the field structure can be made on the basis of this analysis, as shown in FIG. 8.

The example embodiment of the DFET termination virtually eliminates the limitation of using a higher background concentration in the termination region because the applied voltage predominantly drops on the dielectric.

The situation becomes even more advantageous if the termination trench is filled with vacuum, which brings an additional multiplicative factor of 3.9 in equation (7). The inclusion of a vacuum-filled void is not mandatory for the exploitation of the proposed device architecture, but is desirable to the extent it can be manufactured.

Regardless of how the mentioned terminations are derived, they are applied to the case of simple p-n junctions where the background concentration is not increased beyond the one needed to support the target breakdown voltage in plane junctions.

The case of superjunction FETs is more complex in nature due mainly to their characteristic increase in background concentration.

The physical dimensions in all superjunction structures drawn so far, correspond to typical BV_{DSS}=600 V devices and are represented to scale, except for the thin gate and field oxides.

Based on the theory of superjunction devices, the vertical electric field in the FET array region is uniform, hence the ideal total depth of the pillars is

d_{pillar,ideal}=B_{VDSS}/E_{crit}(Si)=600/300,000=0.0020 cm=20 μm,

where Grove's (A. S. Grove, Physics and Technology of Semiconductor Devices, Wiley, 1968) critical field of 300,000 V/cm was used.

However, the actual field distribution has periodic peaks that can be as high as two times the magnitude of the ideal uniform field. Therefore, it is safe to consider a two times deeper pillar, i.e.,

dₚᵢₗₗₐᵣ=2×B_{VDSS}/E_{crit(Si)}=40 μm

which was used in all our drawings.

The horizontal dimensions are represented to scale with respect to the above reference dimensions and can be determined graphically. The essential dimensions of the array defined in FIG. 4 are

a(body width)=8 μm, b(gate width)=12 μm.

While the depth of the pillars may be reduced slightly below the calculated worst-case value for a given breakdown voltage specification, the cell dimensions of the array a and b may change more visibly with scaling the device toward better R_{DS(ON)}×Area performance, as shown in FIG. 4.

The trench depth and width in the inventive structure are represented to the same scale and are

d_{trench}(trench depth)=45 μm, W_{trench}(trench width)=20 μm.

In the case the pillar depth is changed as mentioned before, trench depth tracks the pillar depth, maintaining a reasonable overlap of 5 μm.

All the values provided so far are believed to be reliable reference numbers for starting the array design of a superjunction FET.

Differently from the above, the trench width in our representations may be exaggeratedly large. A “back-of-the-envelope” calculation for a starting design value obtained observing that the entire drain voltage is vertically supported in the silicon array over the dₚᵢₗₗₐᵣ distance and simplifying the termination field structure to a horizontal one. In view of the field structure analysis in FIG. 7, in order to support the same voltage, i.e., to contain the same number of equipotential lines, the trench has to be three times narrower than the pillar is deep, i.e.,

W_{rench,ideal}=dₚᵢₗₗₐᵣ/3=45/3=15 μm.

The trench can be made even narrower if an important portion of it is empty (“filled with vacuum”). Moreover, some residual depletion takes place in the background silicon as represented in FIGS. 6 and 7. Hence, a realistic target value for process development can be

W_{trench,real}=10 μm.

The gate oxide is as thick as it would be in a conventional (non-superjunction) FET for the imposed breakdown voltage. It has to support only the maximum applicable gate voltage, which is around 30 V for a 600 V device. Hence,

t_{Ox}>V_{Gmax}/E_{crit}=30/600=0.05 μm=50 nm.

Based on extensive analysis of state-of-the-art high-voltage power FETs, it is safe to propose a starting value of

t_{OX}=80 nm.

The field oxide can support the entire high voltage, i.e., for a 600 V device,

t_{Fox}>BV_{DSS}/E_{crit}=600/600=1.0 μm.

Based on the same analysis of state-of-the-art high-voltage power FETs, it is safe to propose a starting value of

t_{FOX}=1.5 to 2 μm.

The superjunction literature indicates that the doping of the background material can be as high 10 times the background concentration of a plane junction designed for a given breakdown voltage specification. In our case, for a 600 V

Nₑₚᵢ<10×N_{epi(600 V)}=10×4×10¹⁴ cm⁻³=4×10¹⁵ cm⁻³.

Based on the same analysis of state-of-the-art high-voltage power FETs, it is safe to propose, conservatively, a starting value of

Nₑₚᵢ=1×10¹⁵ cm⁻³.

It is generally understood and is common practice that the final manufacturing values are derived from TOAD calculations started from initial analysis values such as those provided above, followed by computer-assisted experimental optimization. The above design parameters have been provided here for the sole purpose of illustrating the order of magnitude of a generic high-voltage superjunction FET on which our inventive termination would be applied.

The proposed device structure and the discussion in the sections above assume the ideal situation when the dielectric used for filling the termination trench is perfect, i.e., it is free of interface or bulk charges. Deposited or grown oxides can have charges at the interface or in their volume.

In thermally grown oxides, the situation is as follows:

The interface charges, typically positive can be reduced to below 10¹⁰ q/cm², where q is the electronic charge, as a result of the general MOSFET processing experience. This interface charge is much smaller than the charge per unit area in the termination buffer, of

Q_{buffer}/q=N_{buffer}×(a/2)=10¹⁵×4×10⁻⁴=4×10¹¹ cm⁻²,

hence it can be neglected.

The bulk charges have been virtually eliminated in MOSFET processing.

In chemically deposited oxides, the interface or bulk charges can be also reduced to insignificant levels depending of the chemistry used in the respective equipment.

When the interface charge density is of the order of the charge density in the termination buffer, of 4×10¹¹ q cm⁻², the width of the termination buffer can be increased beyond its nominal value of a/2, such that the additional, unbalanced negative charge in it is balanced by the positive charge at the interface. This fine, vernier-like adjustment of the lateral charge balancing will work for charges that do not exceed 10 times the charge density of the nominal buffer.

In cases when the interface charge density exceeds 4×10¹² cm⁻², an angle in-trench implant of boron can be applied, with an additional mask, to increase the charge in the termination buffer such as to balance the excessive oxide charge. This approach has been already used and reported for non-superjunction devices which is conductive, can be implemented with, for example, single-crystal silicon.

Modifications in doping profiles and polarities to obtain p-type and n-type transistors may be made in the described example embodiments. Those skilled in the art will appreciate that other modifications may be made to the described embodiments, and that many other embodiments are also possible within the scope of the claimed invention.

1. An apparatus comprising:
a substrate having a first region of a first conduction type;
a plurality of array pillars of a second conduction type formed in a second region of the substrate and extending to a first depth, wherein the second region is located within the first region, and wherein the plurality of array pillars are substantially parallel to one another;
a boundary pillar of the second conduction type formed along the periphery of the second region and extending to the first depth;
a plurality of array wells formed in the second region of the substrate and extending to a second depth, wherein each array well is at least partially coextensive with at least one of the array pillars, and wherein the first depth is greater than the second depth;
a biasing well formed in the second region of the substrate and extending to the second depth, wherein the biasing well is at least partially coextensive with at least one of the array pillars and the boundary pillar;
a termination pillar formed in the first region of substrate along the periphery of the of the second region and extending to a third depth, wherein the termination pillar abuts the boundary pillar, and wherein the third depth is greater than the first depth;
a boundary gate dielectric strip formed over at least a portion of the biasing well;
a plurality of array gate dielectric strips, wherein each array gate dielectric strip is located between at least two of array pillars, and wherein each array gate dielectric is formed over at least a portion of two array wells;
a boundary gate conductor that is formed over at least a portion of the termination pillar and over at least a portion of the boundary gate dielectric strip;
a plurality of array gate conductors, wherein each array gate conductor is formed over at least a portion of at least one of the array gate dielectric strips;
a first electrode that is formed over at least a portion of the second region of the substrate so as to couple the plurality of array wells and the boundary well together;
a second electrode formed over at least a portion of the termination pillar so as to coupled to plurality of array gate conductors and the boundary gate conductor together; and
a third conductor formed over the substrate along the periphery of the first region.

2. The apparatus of claim 1, wherein the termination pillar further comprises:
a termination pillar trench;
a vacuum-filled region formed within the termination pillar trench; and
a termination pillar dielectric layer formed within the termination pillar trench and substantially surrounding the vacuum-filled region.

3. The apparatus of claim 2, wherein the first electrode is formed over the plurality of array gate conductors, and wherein an isolation dielectric layer is located between each of the array gate conductors and the first electrode.

4. The apparatus of claim 3, wherein the substrate further comprises:
a first substrate layer;
a second substrate layer that underlies the first substrate layer.

5. The apparatus of claim 4, wherein the array wells are of the second conduction type.

6. The apparatus of claim 5, wherein the biasing well is of the second conduction type.

7. The apparatus of claim 6, wherein the first conduction type is N-type, and the second conduction type is P-type.

8. The apparatus of claim 7, wherein the plurality of array conductors and the boundary gate conductor are formed of polysilicon, and wherein the first, second, and third conductors are formed of aluminum, and wherein the first substrate layer is an epitaxial layer.

9. The apparatus of claim 8, wherein the termination pillar dielectric layer further comprise:
a thermally grown silicon dioxide layer; and
a deposited dielectric layer formed over the thermally grown silicon dioxide layer.

10. An apparatus comprising:
a substrate having:
a first layer of a first conduction type with a first doping concentration; and
a second layer of the first conduction type with a second doping concentration that is formed over the first layer, wherein the first doping concentration is greater than the first doping concentration;
a field effect transistor (FET) array having:
a first set of pillars of a second conduction type formed in the second layer of the substrate, wherein the pillars from the first set of pillars are substantially parallel to one another, and wherein each pillar from the first set of pillars extends to a first depth;
a first set of wells formed in the first layer, wherein each well from the first set of wells is at least partially coextensive with at least one of the pillars from the first set of pillars;
a first set of gate dielectric strip formed over the second layer of the substrate, wherein each gate dielectric strip is located between at least two of the pillars from the first set of pillars;
a first set of gate conductors, wherein each gate conductor from the first set of gate conductors is formed over at least a portion of at least one of the gate dielectric strips from the first set of gate dielectric strips; and
a set of gate isolators, wherein each gate isolator is formed over at least a portion of at least one of the gate conductors from the first set of gate conductors;
a terminator having:
a second set of pillars of the second conduction type formed in the second layer of the substrate, wherein the second set of pillars substantially surround the first set of pillars;
a dielectric pillar formed in the second layer of the substrate and abutting the second set of pillars, wherein the dielectric pillar extends to a second depth, and wherein the second depth is greater than the first depth;
a second set of wells formed in the second layer of the substrate, wherein each well from the second set of wells is at least partially coextensive with at least one pillar from each of the first and second sets of pillars;
a second set of gate dielectric strips, wherein each dielectric gate strip from the first set of gate dielectric strips is formed over at least a portion of at least one of wells from the second set of wells; and
a second set of gate conductor, wherein each gate conductor from the second set of gate conductors is formed over the at least a portion of the dielectric pillar and at least one of the gate dielectric strips from the first set of gate dielectric strips;
a first electrode that is formed over the gate isolators and that couples the wells from the first and second sets of wells together;
a second electrode formed over at least a portion of the dielectric pillar so as to coupled to the gate conductors from the first and second sets of gate conductors together; and
a third conductor formed over the substrate and spaced apart from the second electrode.

11. The apparatus of claim 10, wherein the dielectric pillar further comprises:
a trench;
a vacuum-filled region formed within the trench; and
a pillar dielectric layer formed within the trench and substantially surrounding the vacuum-filled region.

12. The apparatus of claim 11, wherein the first set of wells are of the second conduction type having a third doping concentrations, respectively, wherein the third doping concentration is greater than the second doping concentration.

13. The apparatus of claim 12, wherein the first and second sets of pillars have a fourth doping concentration that is less than the third doping concentration.

14. The apparatus of claim 13, wherein the second set of pillars further comprise a boundary pillar, and wherein the second set of wells further comprises a biasing well is of the second conduction type.

15. The apparatus of claim 14, wherein the first conduction type is N-type, and the second conduction type is P-type.

16. The apparatus of claim 15, wherein the gate conductors are formed of polysilicon, and wherein the first, second, and third conductors are formed of aluminum, and wherein the first substrate layer is an epitaxial layer.

17. The apparatus of claim 16, wherein the termination pillar dielectric layer further comprise:
a thermally grown silicon dioxide layer; and
a deposited dielectric layer formed over the thermally grown silicon dioxide layer.
